(19) United States
(12) Patent Application Publication
(10) Pub. No.: US 2017/0264333 A1
(43) Pub. Date: Sep. 14, 2017

(54) SEMICONDUCTOR INTEGRATED CIRCUIT DEVICE AND WIRELESS COMMUNICATION APPARATUS

(71) Applicant: KABUSHIKI KAISHA TOSHIBA, Tokyo (JP)

(72) Inventor: Hiroaki HOSHINO, Yokohama (JP)

(73) Assignee: KABUSHIKI KAISHA TOSHIBA, Tokyo (JP)

(21) Appl. No.: 15/254,300

(22) Filed: Sep. 1, 2016

(30) Foreign Application Priority Data
Mar. 14, 2016 (JP) 2016-050072

(51) Int. Cl. H04B 1/40; H04B 17/21; H03L 7/099; H03L 7/197; H03L 7/089; H03L 7/093

(52) U.S. Cl. CPC H04B 1/40; H03L 7/0891; H03L 7/093; H03L 7/099; H03L 7/197; H04B 17/21

(57) ABSTRACT

According to one embodiment, a semiconductor integrated circuit device includes an oscillator, a frequency divider, and a control circuit. The oscillator is configured to oscillate at a variable oscillation frequency. The frequency divider is configured to oscillate at a variable free-running oscillation frequency, and has a frequency dividing range that transitions according to a variation in the free-running oscillation frequency. The control circuit is configured to control the oscillator to vary the oscillation frequency during a calibration operation that adjusts the oscillation frequency and is configured to control the frequency divider to cause the frequency dividing range to transition based on an amount of variation of the oscillation frequency.

### CROSS-REFERENCE TO RELATED APPLICATION

This application claims the benefit of and priority to Japanese Patent Application No. 2016-050072, filed Mar. 14, 2016, the entire contents of which are incorporated herein by reference.

### FIELD

Embodiments described herein relate generally to a semiconductor integrated circuit device and a wireless communication apparatus.

### BACKGROUND

A wireless communication apparatus is provided with various semiconductor integrated circuit devices. A phase-locked loop (“PLL”) circuit is one of such semiconductor integrated circuit devices. The PLL circuit includes an oscillator and a frequency divider, which divides an oscillation frequency of the oscillator. An example of an operation of the PLL circuit includes a calibration operation which adjusts the oscillation frequency of the oscillator.

In the PLL circuit, the frequency dividing range of the frequency divider is normally set wide so as to allow covering the amount of variation of the oscillation frequency during the calibration operation, and this leads to an increase of power consumption of the frequency divider. On the other hand, if a reduction of the power consumption of the frequency divider is attempted, the frequency dividing range of the frequency divider narrows, and, as a result, the calibration operation may become unstable.

### SUMMARY

In some embodiments according to one aspect, a semiconductor integrated circuit device includes an oscillator, a frequency divider, and a control circuit. The oscillator is configured to oscillate at a variable oscillation frequency. The frequency divider is configured to oscillate at a variable free-running oscillation frequency, and has a frequency dividing range that transitions according to a variation in the free-running oscillation frequency. The control circuit is configured to control the oscillator to vary the oscillation frequency during a calibration operation that adjusts the oscillation frequency and is configured to control the frequency divider to cause the frequency dividing range to transition based on an amount of variation of the oscillation frequency.

In some embodiments according to another aspect, a semiconductor integrated circuit device includes an oscillator configured to oscillate at a variable oscillation frequency, a first frequency divider configured to oscillate at a variable free-running oscillation frequency, and having a first frequency dividing range that transitions according to the free-running oscillation frequency, and a second frequency divider having a second frequency dividing range that transitions according to the free-running oscillation frequency, the second frequency dividing range of the second frequency divider being narrower than the first frequency dividing range of the first frequency divider. The semiconductor integrated circuit device further includes a control circuit configured to control the oscillator to vary the oscillation frequency during a first calibration operation that adjusts the oscillation frequency by causing the first frequency divider to operate and causing the second frequency divider to stop, and further configured to adjust the free-running oscillation frequency during a second calibration operation by causing the first frequency divider to stop and causing the second frequency divider to operate.

Other aspects and embodiments of the disclosure are also encompassed. The foregoing summary and the following detailed description are not meant to restrict the disclosure to any particular embodiment but are merely meant to describe some embodiments of the disclosure.

### BRIEF DESCRIPTION OF THE DRAWINGS

FIG. 1 is a block diagram illustrating a configuration of a semiconductor integrated circuit device according to a first embodiment.

FIG. 2 is a circuit diagram illustrating an example of a configuration of an oscillator.

FIG. 3 is a graph illustrating a frequency characteristic of the oscillator illustrated in FIG. 2.

FIG. 4 is a circuit diagram illustrating an example of a configuration of a frequency divider.

FIG. 5 is a graph illustrating an example frequency characteristic of the frequency divider illustrated in FIG. 4.

FIG. 6 is a flowchart illustrating an example of a procedure for a calibration operation which adjusts a free-running oscillation frequency.

FIG. 7 is a diagram illustrating an operation performed in step S14 to step S16 in the flowchart illustrated in FIG. 6.

FIG. 8 is a diagram illustrating an example offset calibration.

FIG. 9 is a flowchart illustrating an example procedure for a calibration operation which adjusts an oscillation frequency.

FIG. 10 is a block diagram illustrating a configuration of a semiconductor integrated circuit device according to a modification example.

FIG. 11 is a circuit diagram illustrating an example of a configuration of an oscillator according to the modification example.

FIG. 12 is a block diagram illustrating a configuration of a principal portion of a semiconductor integrated circuit device according to a second embodiment.

FIG. 13 is a flowchart illustrating an example operating procedure for the semiconductor integrated circuit device according to the second embodiment.

FIG. 14 is a block diagram illustrating a schematic configuration of a wireless communication apparatus.

### DETAILED DESCRIPTION

According to some embodiments, there is provided a semiconductor integrated circuit device and a wireless communication apparatus which are capable of reducing the power consumption of a frequency divider and also stabilizing a calibration operation.

In general, according to some embodiments, a semiconductor integrated circuit device includes an oscillator, a frequency divider, and a control circuit. The oscillator oscillates at a variable oscillation frequency. The frequency divider oscillates by itself at a variable free-running oscillation frequency, and has a frequency dividing range that transitions according to a variation in the free-running oscillation frequency. The control circuit controls the oscillator to vary the oscillation frequency during a calibration operation that adjusts the oscillation frequency and controls the frequency divider to cause the frequency dividing range to transition based on an amount of variation of the oscillation frequency.

Hereinafter, some example embodiments will be described with reference to the drawings. The embodiments described herein are not meant to be limiting.

### First Embodiment

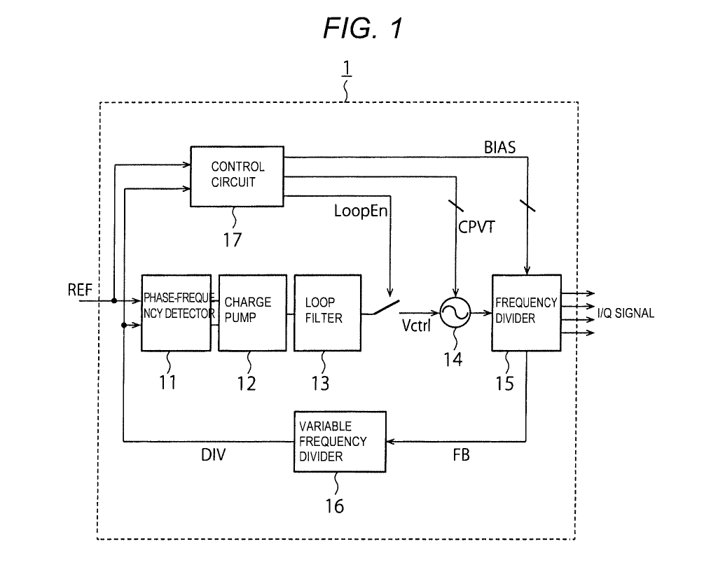

FIG. 1 is a block diagram illustrating a configuration of a semiconductor integrated circuit device according to a first example embodiment. The semiconductor integrated circuit device 1 illustrated in FIG. 1 can be applied to an analog phase-locked loop (“PLL”) circuit. The analog PLL circuit can perform feedback control to synchronize a phase of a frequency-divided signal DIV, which can be an output signal of a variable frequency divider, with a phase of a reference signal REF. The reference signal REF can be a pulse signal (such as a clock signal) used as a criterion for phase synchronization, and the frequency-divided signal DIV can be a signal used as a target of phase comparison with the reference signal REF. Synchronizing the phases of these signals can allow a signal with a frequency corresponding to a reference frequency of the reference signal REF to be stably output from, for example, the semiconductor integrated circuit device 1.

The semiconductor integrated circuit device 1 according to the first embodiment includes a phase-frequency detector 11, a charge pump 12, a loop filter 13, an oscillator 14, a frequency divider 15, a variable frequency divider 16, and a control circuit 17.

The phase-frequency detector 11 detects a phase difference between the frequency-divided signal DIV, which is an output signal of the variable frequency divider 16, and the reference signal REF. Moreover, the phase-frequency detector 11 outputs a signal with a pulse width corresponding to the phase difference to the charge pump 12.

The charge pump 12 supplies a current to the loop filter 13 or extracts a current from the loop filter 13, based on a signal input from the phase-frequency detector 11.

The loop filter 13 converts the current supplied or extracted from the charge pump 12 into a voltage and performs smoothing on the voltage. As a result, a voltage control signal Vctrl is generated. The voltage control signal Vctrl is an analog signal.

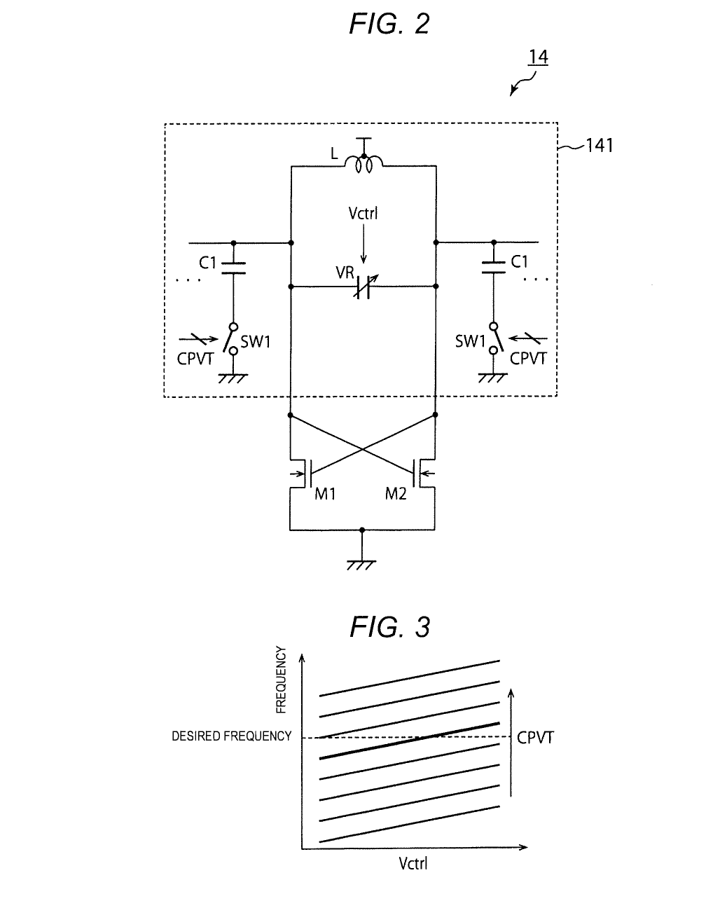

The oscillator 14 generates and outputs an oscillating signal. The oscillation frequency of the oscillating signal is variable. Here, a configuration of the oscillator 14 is described with reference to FIG. 2.

FIG. 2 is a circuit diagram illustrating an example of a configuration of the oscillator 14. The oscillator 14 illustrated in FIG. 2 is a voltage-controlled oscillator (VCO), the oscillation frequency of which is controlled by an input voltage. More specifically, the oscillator 14 includes a resonant circuit 141, which includes a plurality of switches SW1 (first switches), and a pair of N-type metal-oxide semiconductor (MOS) transistors M1 and M2.

The resonant circuit 141 includes an inductor L, a variable capacitance element VR (hereinafter, referred to as a varactor VR), a plurality of capacitors C1, and the plurality of switches SW1, each one of which is respectively connected in series with one capacitor of the plurality of capacitors C1. The inductor L and the varactor VR are connected in parallel. Capacitor-switch pairings of the plurality of capacitors C1 and the plurality of switches SW1 are connected in parallel to each other with respect to a circuit composed of the inductor L and the varactor VR. Current can be supplied to the inductor L. In the resonant circuit 141, the capacitance of the varactor VR is set by the voltage control signal Vctrl input from the loop filter 13, and the equivalent capacitances of the plurality of capacitors C1 and the plurality of switches SW1 are set by the plurality of switches SW1. The resonant frequency of the resonant circuit 141 is set by the setting of these capacitances. This resonant frequency is, in other words, the oscillation frequency of the oscillator 14. Thus, the oscillation frequency of the oscillator 14 is set by the capacitance of the varactor VR and the equivalent capacitances of the plurality of capacitors C1 and the plurality of switches SW1.

The N-type MOS transistors M1 and M2 are connected, what is called, in a cross-coupled manner with respect to the resonant circuit 141. In the resonant circuit 141, oscillation may stop due to resistive losses caused by a parasitic resistance of the inductor L and a parasitic resistance of the varactor VR. However, in the present embodiment, the N-type MOS transistors M1 and M2, which are connected in a cross-coupled manner, compensate for the resistive losses, and, in other words, are configured as a negative resistance circuit that can cancel the above-mentioned parasitic resistances. Therefore, the resistive losses are compensated for by the N-type MOS transistors M1 and M2, so that oscillation continues.

Each one of the plurality of switches SW1 is respectively connected in series with one capacitor of the plurality of capacitors C1. Each switch SW1 operates based on a control signal CPVT input from the control circuit 17. The control signal CPVT is a digital signal.

FIG. 3 is a graph illustrating a frequency characteristic of the oscillator 14. In FIG. 3, the horizontal axis indicates a magnitude of the voltage control signal Vctrl, and the vertical axis indicates an oscillation frequency. As illustrated in FIG. 3, the oscillation frequency varies according to the magnitude of the voltage control signal Vctrl. Moreover, the number of capacitors C1 to be grounded varies based on the control signal CPVT input to the switches SW1. Therefore, the oscillation frequency also varies according to the operations of the switches SW1. In the oscillator 14, in a case where the oscillation frequency is to be set to a desired frequency, the oscillation frequency is subjected to fine adjustment by the voltage control signal Vctrl and is also subjected to coarse adjustment by the control signal CPVT. Here, the term “fine adjustment” refers to finely adjusting the oscillation frequency of the oscillator 14 by setting the capacitance value of the varactor VR using the voltage control signal Vctrl. Moreover, the term “coarse adjustment” refers to coarsely adjusting the oscillation frequency of the oscillator 14 by selecting capacitors C1 to be grounded using the control signal CPVT.

Referring back to FIG. 1, the frequency divider 15 frequency-divides the oscillating signal input from the oscillator 14 and outputs an I signal, a Q signal, which is orthogonal in phase to the I signal, and an FB signal, which is used for feedback control of phase and frequency. An I/Q signal, which represents both the I signal and the Q signal, depends on an output signal of the semiconductor integrated circuit device 1. The I/Q signal is used to orthogonally demodulate a received signal, which is received via, for example, an antenna, or is used to orthogonally modulate a transmitting signal, which, for example, is to be transmitted from an antenna. Moreover, the FB signal, which is a periodic signal, is converted into the frequency-divided signal DIV by the variable frequency divider 16.

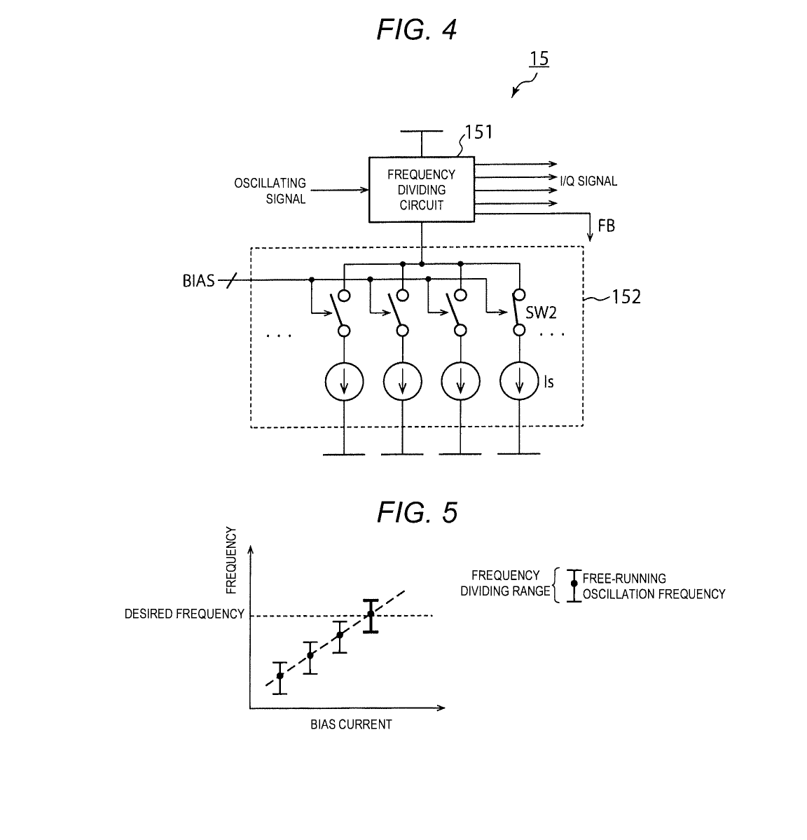

FIG. 4 is a circuit diagram illustrating an example of a configuration of the frequency divider 15. The frequency divider 15 illustrated in FIG. 4 includes a frequency dividing circuit 151 and a bias current setting circuit 152. The frequency dividing circuit 151 includes, for example, a ring oscillator. The bias current setting circuit 152 includes a plurality of current sources Is and a plurality of switches SW2 (second switches).

The plurality of current sources Is is connected as a bias circuit for the frequency dividing circuit 151, and the plurality of current sources Is can be connected in parallel with each other with respect to the frequency dividing circuit 151. Each current source Is supplies a bias current to vary the free-running oscillation frequency of the frequency dividing circuit 151. Each one of the plurality of switches SW2 is respectively connected in series with one current source of the plurality of current sources Is. Each switch SW2 operates based on a control signal BIAS input from the control circuit 17.

When the oscillator 14 is operating, the frequency dividing circuit 151 frequency-divides the oscillating signal of the oscillator 14 and outputs the I/Q signal and the FB signal. Conversely, when the oscillator 14 is stopped, the frequency dividing circuit 151 oscillates by itself at a variable free-running oscillation frequency to output the FB signal. The frequency of the FB signal depends on the free-running oscillation frequency.

FIG. 5 is a graph illustrating a frequency characteristic of the frequency divider 15. In FIG. 5, the horizontal axis indicates a magnitude of a bias current, and the vertical axis indicates a free-running oscillation frequency. As illustrated in FIG. 5, the free-running oscillation frequency varies based on the magnitude of the bias current. Moreover, the frequency dividing range of the frequency divider 15 transitions according to the free-running oscillation frequency.

The free-running oscillation frequency depends on a charge-discharge time of each stage of the ring oscillator. The charge-discharge time depends on the bias current input to the frequency dividing circuit. The magnitude of the bias current input to the frequency dividing circuit varies according to the states of the switches SW2. For example, as the number of switches SW2 that are in an on-state increases, the bias current input to the frequency dividing circuit becomes larger. As a result, the charge-discharge time becomes shorter and the free-running oscillation frequency becomes higher.

Referring back to FIG. 1 again, the variable frequency divider 16 frequency-divides the FB signal input from the frequency divider 15 by a frequency division ratio set by the control circuit 17. The relationship expressed by the following formula (1) exists between the frequency division ratio N of the variable frequency divider 16, a reference frequency f1 of the reference signal REF, and a frequency f2 of the I/Q signal.

f2=f1×N (1)

The control circuit 17 controls inputting of the voltage control signal Vctrl from the loop filter 13 to the oscillator 14 using a control signal LoopEn. When the control signal LoopEn is set as “0”, the voltage control signal Vctrl is not input from the loop filter 13 to the oscillator 14. Conversely, when the control signal LoopEn is set as “1”, the voltage control signal Vctrl is input from the loop filter 13 to the oscillator 14.

Furthermore, the control circuit 17 varies the oscillation frequency of the oscillator 14 using the control signal CPVT. Moreover, the control circuit 17 varies the free-running oscillation frequency of the frequency divider 15 using the control signal BIAS.

Next, an example operation of the semiconductor integrated circuit device 1 according to the present embodiment is described. Here, example calibration operations which respectively adjust the oscillation frequency and the free-running oscillation frequency are described.

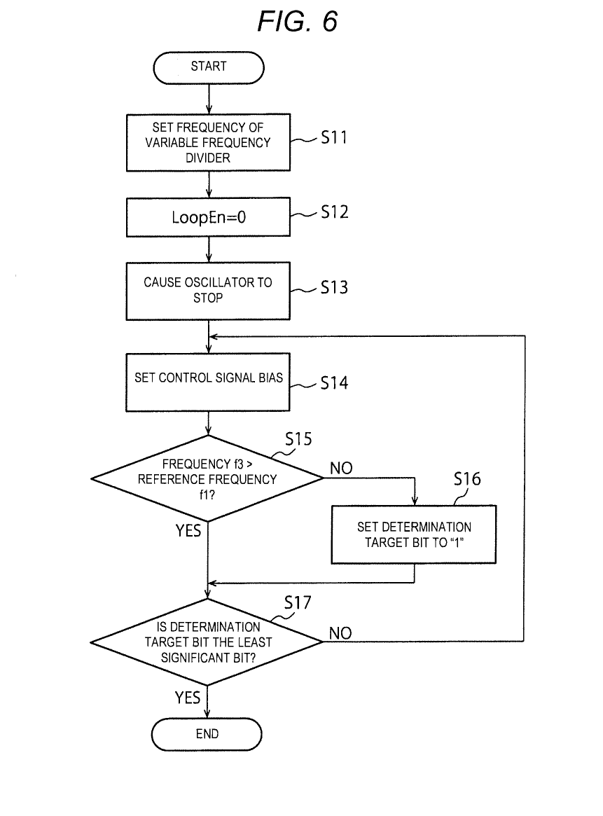

FIG. 6 is a flowchart illustrating an example procedure for a calibration operation which adjusts the free-running oscillation frequency.

First, in step S11, the control circuit 17 sets a frequency division ratio of the variable frequency divider 16. At this time, the control circuit 17 determines the frequency division ratio based on the above-mentioned formula (1).

Then, in step S12, the control circuit 17 outputs the control signal LoopEn set as “0”. This interrupts inputting of the voltage control signal Vctrl from the loop filter 13 to the oscillator 14. After that, in step S13, the control circuit 17 causes the oscillator 14 to stop. For example, the control circuit 17 causes the oscillator 14 to stop by removing the connection between the indictor L and a path for supplying current to the inductor L. This brings the frequency divider 15 into a state of being able to oscillate at the free-running oscillation frequency.

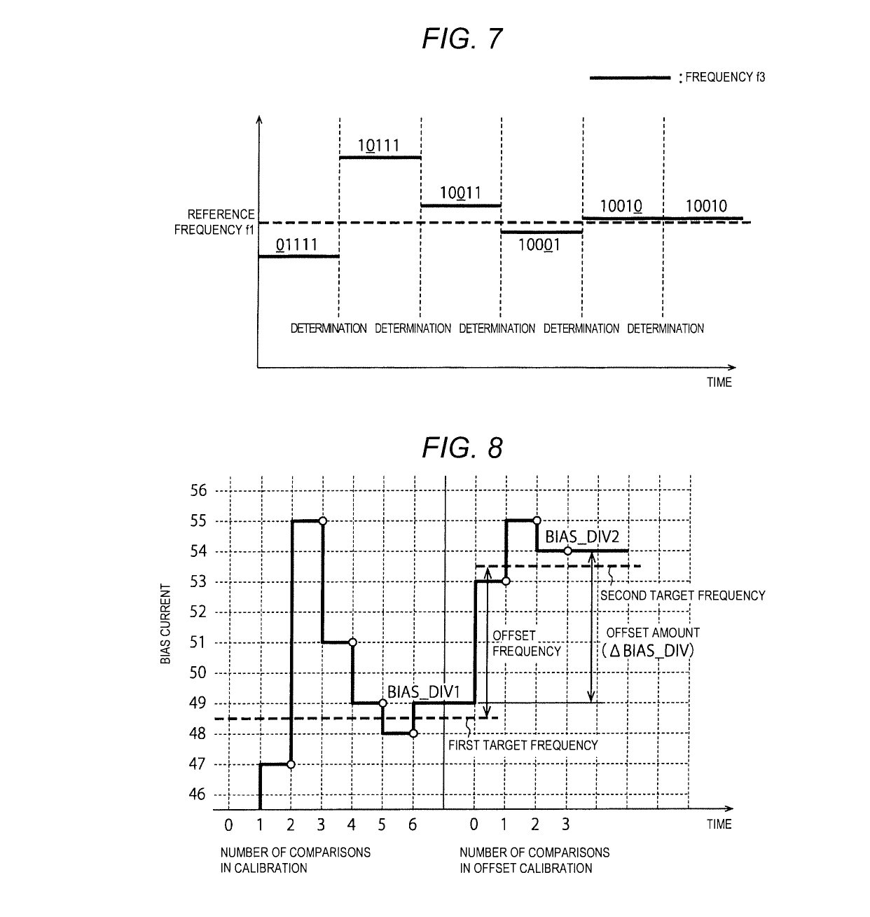

FIG. 7 is a diagram illustrating an example operation performed in step S14 to step S16 in the flowchart illustrated in FIG. 6. A serial operation performed in step S14 to step S16 is described below with reference to FIGS. 6 and 7.

In step S14, the control circuit 17 sets the control signal BIAS. More specifically, at the first determination, the control circuit 17 sets a most significant bit (“MSB”) of the control signal BIAS as “0”, and sets that bit as a determination target bit, and sets all of the bits lower than the determination target bit as “1”. For example, in a case where the control signal BIAS is composed of 5 bits, the bits of the control signal BIAS become “01111”. The bits of the control signal BIAS indicate the states of the respective switches SW2. Thus, the bits of the control signal BIAS indicate a magnitude of the bias current input to the frequency dividing circuit. From the second determination on, a bit that is one bit lower than the former determination target bit is used as a new determination target bit.

In the frequency divider 15, the FB signal is generated based on the control signal BIAS, and then, the FB signal is frequency-divided into the frequency-divided signal DIV by the variable frequency divider 16. After that, the frequency-divided signal DIV is input to the control circuit 17. At this time, the reference signal REF is also input to the control circuit 17.

In step S15, the control circuit 17 compares the reference frequency f1 of the reference signal REF and the frequency f3 of the frequency-divided signal DIV with each other. If the frequency f3 is lower than or equal to the reference frequency f1 (NO in step S15), then in step S16, the control circuit 17 sets the determination target bit as “1”. Conversely, if the frequency f3 is higher than the reference frequency f1 (YES in step S15), the control circuit 17 keeps the determination target bit as “0”.

Then, in step S17, the control circuit 17 determines whether the determination target bit is the least significant bit. If the determination target bit is not the least significant bit (NO in step S17), the control circuit 17 returns to the operation in the above-mentioned step S14. Then, in step S14, the control circuit 17 sets a bit that is one bit lower than the determination target bit of the control signal BIAS as “0” for the new determination target bit, and sets all of the bits lower than the set bit as “1”.

Subsequently, the control circuit 17 sets the determination target bit as “0” or “1” based on a result of comparison between the frequency f3 of the frequency-divided signal DIV generated based on the control signal BIAS and the reference frequency f1. Until the determination target bit reaches the least significant bit, the control circuit 17 repeats the setting operation of the control signal BIAS and the comparison operation between the reference frequency f1 and the frequency f3. When the determination target bit reaches the least significant bit, the calibration operation which adjusts the free-running oscillation frequency ends. A first target frequency, which is a target frequency of this calibration operation, is a frequency at a time of start of calibration of the oscillator 14, which is described in more detail below. When the calibration operation ends, the free-running oscillation frequency is adjusted to a frequency that is in the vicinity of the first target frequency. When the calibration operation ends, the free-running oscillation frequency can be adjusted to a frequency that is substantially the same as the first target frequency.

In the present embodiment, an example offset calibration is performed between the calibration operation of the frequency divider 15 and the calibration operation of the oscillator 14. The offset calibration is described below with reference to FIG. 8.

FIG. 8 is a diagram illustrating the example offset calibration. In FIG. 8, the term “number of comparisons in calibration” refers to the number of times for which the reference frequency f1 and the frequency f3 have been compared with each other during the calibration operation for the free-running oscillation frequency. The term “number of comparisons in offset calibration” refers to the number of times for which the reference frequency f1 and the frequency f3 have been compared with each other during the offset calibration operation.

The first target frequency is, as mentioned above, a frequency at the time of start of calibration of the oscillator 14, with the calibration being performed after the offset calibration. Moreover, a second target frequency is a free-running oscillation frequency which serves as a target after the start of calibration of the oscillator 14. The second target frequency is obtained by adding an offset frequency to the first target frequency. The offset frequency depends on an amount of variation of the oscillation frequency after the first frequency comparison is performed in the calibration of the oscillator 14. For example, in a case where the control signal CPVT is composed of 5 bits, the offset frequency depends on the amount of frequency variation when the control signal CPVT has changed from “01111” to “10111” or from “01111” to “00111”. Furthermore, it is supposed that the amount of frequency variation from “01111” to “10111” and the amount of frequency variation from “01111” to “00111” are almost equal or are substantially equal. Thus, the second target frequency is a target frequency determined based on the amount of variation of the oscillation frequency.

An offset amount ΔBIAS_DIV is a difference between bias currents set before and after the offset calibration, and is expressed by the following formula (2).

ΔBIAS_DIV=BIAS_DIV2−BIAS_DIV1 (2)

In the above formula (2), BIAS_DIV1 denotes a bias current set after the calibration operation for the free-running oscillation frequency. BIAS_DIV2 denotes a bias current set after the offset calibration.

In the offset calibration, as in the operation performed in steps S14 to S17, the control circuit 17 adjusts the bias current so as to bring the free-running oscillation frequency of the frequency divider 15 closer to the second target frequency. Here, the second target frequency is a previously set frequency.

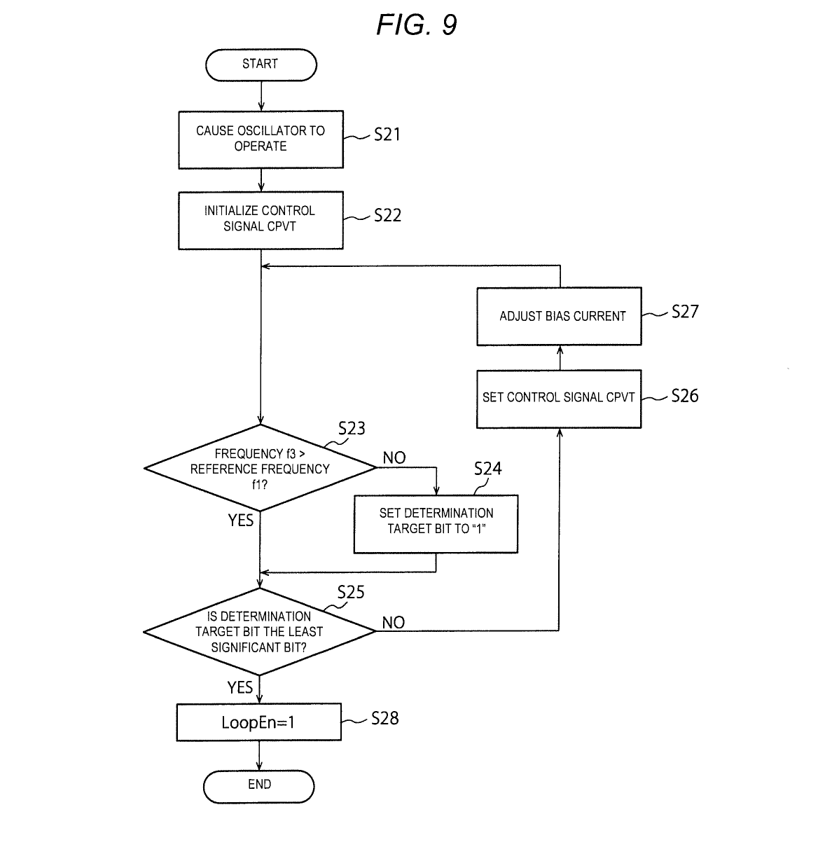

FIG. 9 is a flowchart illustrating a procedure for the calibration operation which adjusts the oscillation frequency.

First, in step S21, the control circuit 17 causes the oscillator 14 to operate. For example, the control circuit 17 connects the inductor L to the path used to supply current to the inductor L, thus causing the oscillator 14 to operate.

Then, in step S22, the control circuit 17 initializes the control signal CPVT. More specifically, the control circuit 17 sets the most significant bit of the control signal CPVT as “0” and sets that bit as a determination target bit, and sets all of the bits lower than the determination target bit as “1”. The bits of the control signal CPVT indicate the states of the respective switches SW1. Thus, the bits of the control signal CPVT correspond to a magnitude of the oscillation frequency.

The oscillator 14 outputs an oscillating signal generated based on the initialized control signal CPVT to the frequency divider 15. The frequency divider 15 frequency-divides the oscillating signal into the FB signal. At this time, in order for the oscillation frequency of the oscillating signal to fall within the frequency dividing range of the frequency divider 15, the free-running oscillation frequency of the frequency divider 15 is not in the vicinity of the second target frequency set after the offset calibration but is in the vicinity of the first target frequency set before the offset calibration. At this time, the free-running oscillation frequency of the frequency divider 15 can be closer to the first target frequency than to the second target frequency.

The FB signal output from the frequency divider 15 is frequency-divided by the variable frequency divider 16 into the frequency-divided signal DIV. Then, the frequency-divided signal DIV is input to the control circuit 17. At this time, the reference signal REF is also input to the control circuit 17.

In step S23, the control circuit 17 compares the reference frequency f1 of the reference signal REF and the frequency f3 of the frequency-divided signal DIV with each other. If the frequency f3 is lower than or equal to the reference frequency f1 (NO in step S23), then in step S24, the control circuit 17 sets the determination target bit as “1”. Conversely, if the frequency f3 is higher than the reference frequency f1 (YES in step S23), the control circuit 17 keeps the determination target bit as “0”.

Then, in step S25, the control circuit 17 determines whether the determination target bit is the least significant bit. If the determination target bit is not the least significant bit (NO in step S25), then in step S26, the control circuit 17 sets the control signal CPVT. More specifically, the control circuit 17 sets a bit that is one bit lower than the determination target bit of the control signal CPVT as “0” the new determination target bit, and sets all of the bits lower than the set bit as “1”. As a result, the oscillation frequency of the oscillator 14 varies.

Then, in step S27, the control circuit 17 adjusts the bias current for the frequency divider 15 so that the oscillation frequency falls within the frequency dividing range of the frequency divider 15. The operation performed in step S27 is described below.

For example, in a case where the most significant bit of the control signal BIAS is set as “1” as a result of the first comparison between the reference frequency f1 and the frequency f3, at the time of the second comparison, the bias current is set as “BIAS_DIV1+ΔBIAS_DIV” by the control circuit 17. Conversely, in a case where the most significant bit of the control signal BIAS is set as “0”, the bias current is set as “BIAS_DIV1−ΔBIAS_DIV”. This ΔBIAS_DIV is the above-mentioned offset amount, and is previously calculated during the offset calibration. Subsequently, at the time of an n-th comparison, “ΔBIAS_DIV/(2⁽ⁿ⁻²⁾)” is added to or subtracted from the last bias current according to a result of the last comparison.

After the operation in step S27 ends, the control circuit 17 returns to the operation in step S23 and sets the determination target bit of the control signal CPVT as “0” or “1” based on a result of comparison between the frequency f3 generated based on the control signal CPVT set in step S26 and the reference frequency f1. Until the determination target bit of the control signal CPVT reaches the least significant bit, the control circuit 17 repeats the setting operation of the control signal CPVT, the adjustment operation of the bias current control signal BIAS, and the comparison operation between the reference frequency f1 and the frequency f3.

When the determination target bit of the control signal CPVT reaches the least significant bit (YES in step S25), then in step S28, the control circuit 17 switches the set control signal LoopEn from “0” to “1”. Then, the calibration operation which adjusts the oscillation frequency ends. After this calibration operation, the semiconductor integrated circuit device 1 performs an operation for feedback control so that the phase of the frequency-divided signal DIV output from the variable frequency divider 16 becomes substantially equal to the phase of the reference signal REF.

According to the above-described embodiment, at the time of the calibration operation which adjusts the oscillation frequency, the control circuit 17 varies the oscillation frequency using the control signal CPVT and also controls the bias current for the frequency divider 15 using the control signal BIAS so that the varied oscillation frequency falls within the frequency dividing range. Therefore, even in a case where a frequency divider with a narrow frequency dividing range, in other words, a frequency divider using much less power, is used, the calibration operation of the oscillator can be stabilized.

### Modification Example

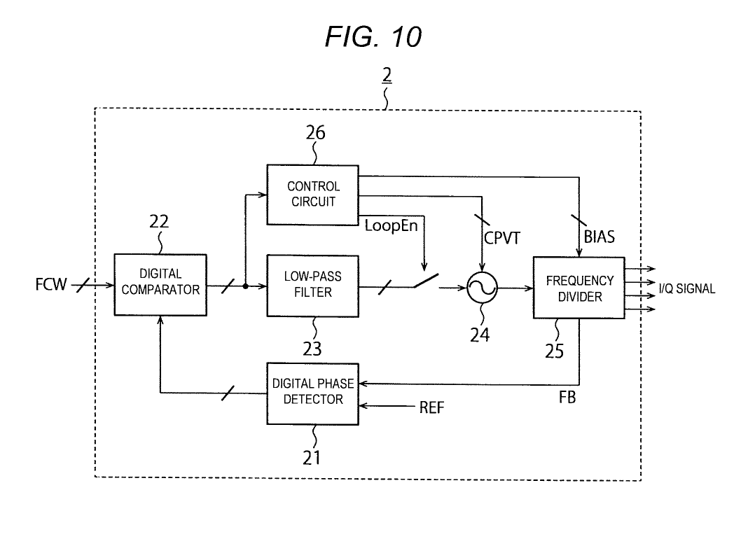

FIG. 10 is a block diagram of a semiconductor integrated circuit device according to a modification example. The semiconductor integrated circuit device 2 illustrated in FIG. 10 can be applied to an all-digital phase-locked loop (“ADPLL”) circuit, which is implemented by digitizing an analog PLL circuit.

An example embodiment of a semiconductor integrated circuit device 2 includes a digital phase detector 21, a digital comparator 22, a low-pass filter 23, an oscillator 24, a frequency divider 25, and a control circuit 26.

The digital phase detector 21 detects the phase of the FB signal output from the frequency divider 25 based on the reference signal REF. More specifically, the digital phase detector 21 detects how many cycles of the FE signal, including any fractional portion, to which one cycle of the reference signal REF corresponds, thus detecting the phase of the FB signal.

The digital comparator 22 compares a reference phase obtained by cumulating frequency control code FCW and the phase output from the digital phase detector 21 with each other, and outputs a signal indicating a difference between these phases. The frequency control code FCW is a signal indicating how many cycles of a desired frequency to which one cycle of the reference frequency f1 corresponds.

The low-pass filter 23 removes a high-frequency component contained in the signal input from the digital comparator 22.

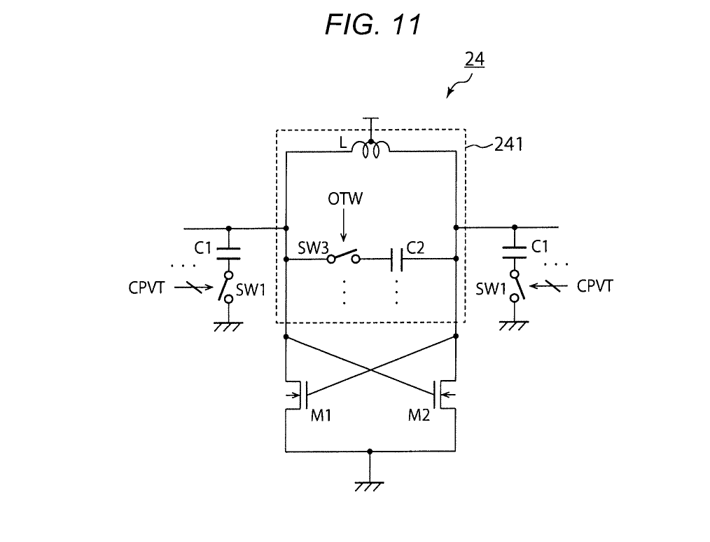

The oscillator 24 generates and outputs an oscillating signal. The oscillation frequency of the oscillating signal is variable. An example configuration of the oscillator 24 is described below with reference to FIG. 11.

FIG. 11 is a circuit diagram illustrating an example of a configuration of the oscillator 24. The oscillator 24 illustrated in FIG. 11 is a digitally controlled oscillator (“DCO”), which is digitally controlled. More specifically, the oscillator 24 includes a resonant circuit 241, a plurality of capacitors C1, a plurality of switches SW1, and a pair of N-type MOS transistors M1 and M2. Since the constituent elements or a configuration other than the resonant circuit 241 can be similar in some respects to those of the oscillator 14 described above, the description thereof is omitted, and the following describes the resonant circuit 241.

The resonant circuit 241 includes an inductor L, a plurality of capacitors C2, and a plurality of switches SW3. The inductor L and the plurality of capacitors C2 are connected in parallel.

Each switch of the plurality of switches SW3 is respectively connected in series with one capacitor of the plurality of capacitors C2. The plurality of switches SW3 operates based on a control signal OTW. The control signal OTW is a digital signal. The number of capacitors C2 connected to the inductor L is based on the states of the respective switches SW3, and the oscillation frequency is set according to the number of capacitors C2 so-connected.

Referring back to FIG. 10, as with the frequency divider 15 illustrated in FIG. 4, the frequency divider 25 frequency-divides the oscillating signal input from the oscillator 24, thus outputting the I/Q signal and the FE signal. Since the configuration and elements of the frequency divider 25 can be similar in some respects to the configuration and elements of the frequency divider 15 illustrated in FIG. 4, the description thereof is omitted.

The control circuit 26 performs the calibration operation of the oscillator 24 and the calibration operation of the frequency divider 25 based on the signal input from the digital comparator 22. Since these calibration operations can be similar in some respects to the calibration operations described in the first embodiment, the description thereof is omitted.

According to the above-described modification example, in a manner similar to the implementation corresponding to the first embodiment, at the time of the calibration operation which adjusts the oscillation frequency, the control circuit 26 varies the oscillation frequency using the control signal CPVT and also controls the bias current for the frequency divider 25 using the control signal BIAS so that the varied oscillation frequency falls within the frequency dividing range. Therefore, even in a case where the semiconductor integrated circuit device 2 according to the modification example is applied to an ADPLL circuit, the power consumption of the frequency divider can be reduced and the calibration operation of the oscillator can also be stabilized.

### Second Embodiment

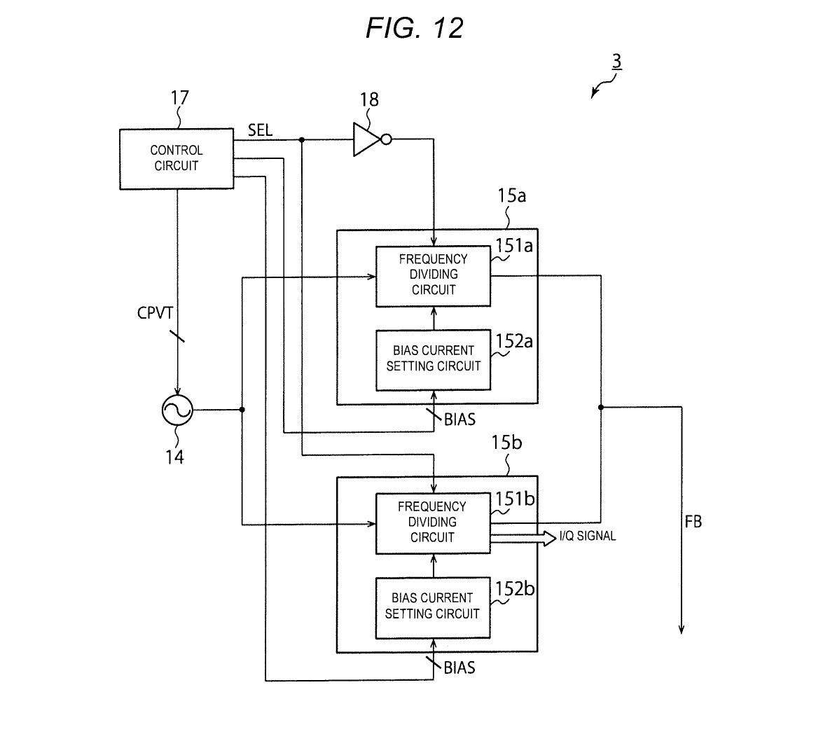

FIG. 12 is a block diagram illustrating an example configuration of a principal portion of a semiconductor integrated circuit device according to a second embodiment. In FIG. 12, a configuration of the portion including the oscillator 14 and circuits connected subsequent thereto is illustrated. Since the configuration of a portion ahead of the oscillator 14 can be similar in some respects to that in the first embodiment, the description thereof is omitted.

As illustrated in FIG. 12, the semiconductor integrated circuit device 3 according to the present embodiment can differ from the semiconductor integrated circuit device 1 in the first embodiment in some ways, including in that a first frequency divider 15a and a second frequency divider 15b are provided in place of the frequency divider 15.

The first frequency divider 15a includes a frequency dividing circuit 151a and a bias current setting circuit 152a. The frequency dividing circuit 151a includes, for example, a current mode logic (“CML”) type frequency dividing circuit. The configuration of the bias current setting circuit 152a is similar in some respects to that of the bias current setting circuit 152 described in the first embodiment.

The second frequency divider 15b includes a frequency dividing circuit 151b and a bias current setting circuit 152b. The frequency dividing circuit 151b includes, for example, an injection-locked frequency divider (“ILFD”) type frequency dividing circuit. The frequency dividing range of the frequency dividing circuit 151b is narrower than the frequency dividing range of the frequency dividing circuit 151a. As a result, the power consumption of the second frequency divider 15b is smaller than the power consumption of the first frequency divider 15a. The configuration of the bias current setting circuit 152b is also similar in some respects to that of the bias current setting circuit 152 described in the first embodiment.

An example operation of the semiconductor integrated circuit device 3 according to the present embodiment is described below.

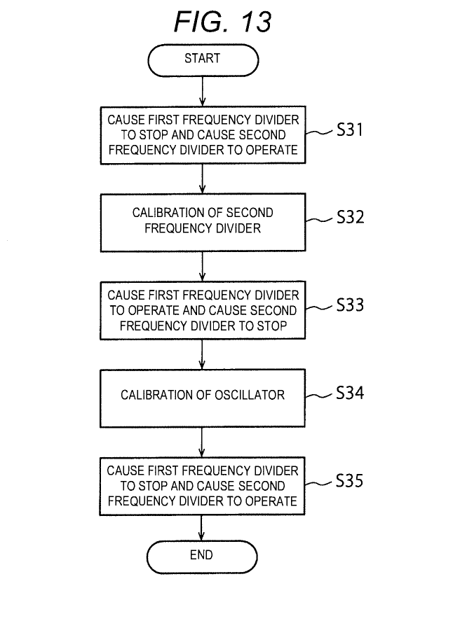

FIG. 13 is a flowchart illustrating an example operating procedure for the semiconductor integrated circuit device 3 according to the present embodiment.

First, in step S31, the control circuit 17 causes the first frequency divider 15a to stop, and also causes the second frequency divider 15b to operate. For example, the control circuit 17 outputs a signal SEL to drive the frequency dividing circuit 151b. This signal SEL, which is also output toward the frequency dividing circuit 151a, is inverted by a NOT circuit 18 and is thus not used to drive the frequency dividing circuit 151a.

Next, in step S32, the control circuit 17 performs a calibration operation which adjusts the free-running oscillation frequency of the second frequency divider 15b (second calibration operation). This calibration operation can be performed in a procedure similar in some respects to that in the operation performed in steps S11 to S17 described in the first embodiment.

Then, in step S33, the control circuit 17 causes the first frequency divider 15a to operate, and also causes the second frequency divider 15b to stop. For example, the control circuit 17 outputs a signal SEL to stop the frequency dividing circuit 151b. This signal SEL, which is also output toward the frequency dividing circuit 151a, is inverted by the NOT circuit 18 and is thus used to drive the frequency dividing circuit 151a.

Next, in step S34, the control circuit 17 performs a calibration operation which adjusts the oscillation frequency of the oscillator 14 (first calibration operation). This calibration operation can be performed in a procedure similar in some respects to that in the operation performed insteps S21 to S28 described in the first embodiment. However, in the present embodiment, since the frequency dividing range of the first frequency divider 15a is wide, the bias current for the first frequency divider 15a is not re-adjusted each time the control signal CPVT is set. Thus, the operation in step S27 is not performed.

Then, in step S35, the control circuit 17 causes the first frequency divider 15a to stop again, and also causes the second frequency divider 15b to operate again. Then, the calibration operation which adjusts the oscillation frequency of the oscillator 14 ends. After this calibration operation, the semiconductor integrated circuit device 3 performs an operation for feedback control so that the phase of the frequency-divided signal DIV output from the variable frequency divider 16 becomes substantially equal to the phase of the reference signal REF. The I/Q signal is generated and output by the frequency dividing circuit 151b of the second frequency divider 15b.

According to the second embodiment, the control circuit 17 selects the second frequency divider 15b, which has a narrow frequency dividing range, in other words, uses much less power, to be used for the calibration operation for the free-running oscillation frequency, and selects the first frequency divider 15a, which has a wide frequency dividing range, to be used for the calibration operation for the oscillation frequency. Therefore, the power consumption of the frequency divider can be reduced and the calibration operation of the oscillator can also be stabilized.

In the present embodiment, a frequency divider used for the calibration operation for the free-running oscillation frequency is different from a frequency divider used for the calibration operation for the oscillation frequency. Therefore, the calibration operation for the oscillation frequency can be performed in advance of the calibration operation for the free-running oscillation frequency. In this way, even when the calibration operations are interchanged, the power consumption of the frequency divider can be reduced and the calibration operation of the oscillator can also be stabilized.

Furthermore, the semiconductor integrated circuit device 3 according to the present embodiment can also be applied to the semiconductor integrated circuit device 2 in the modification example, namely an ADPLL circuit.

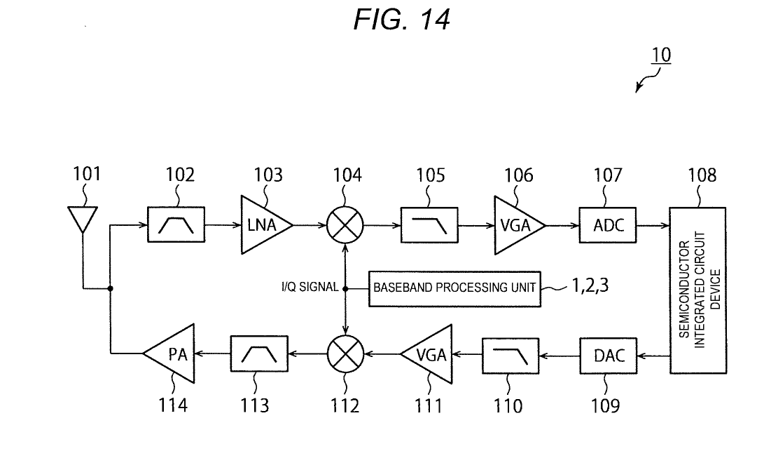

Next, an embodiment in which any one of the above-described semiconductor integrated circuit devices 1 to 3 is applied to a wireless communication apparatus is described with reference to FIG. 14.

FIG. 14 is a block diagram illustrating an example schematic configuration of a wireless communication apparatus. The wireless communication apparatus 10 illustrated in FIG. 14 is an apparatus conforming to Bluetooth®. The wireless communication apparatus 10 includes, in addition to any one of the semiconductor integrated circuit devices 1 to 3, an antenna 101, a high-frequency filter 102, a low noise amplifier 103, a mixer 104, a baseband filter 105, a variable gain amplifier 106, an analog-digital converter 107, a baseband processing unit 108, a digital-analog converter 109, a baseband filter 110, a variable gain amplifier 111, a mixer 112, a high-frequency filter 113, and a power amplifier 114.

In the above-mentioned constituent elements, the high-frequency filter 102, the low noise amplifier 103, the mixer 104, the baseband filter 105, the variable gain amplifier 106, and the analog-digital converter 107 configure a receiving circuit. Furthermore, the digital-analog converter 109, the baseband filter 110, the variable gain amplifier 111, the mixer 112, the high-frequency filter 113, and the power amplifier 114 configure a transmitting circuit.

First, the receiving circuit is described. A received signal, which is obtained by the antenna 101 receiving a first radio signal, is subjected to rough channel selection by the high-frequency filter 102, and is then input to the low noise amplifier 103.

The output signal of the low noise amplifier 103 is input to the mixer 104. The I/Q signal output from any one of the semiconductor integrated circuit devices 1 to 3 is also input to the mixer 104. The mixer 104 and any one of the semiconductor integrated circuit devices 1 to 3 configure a demodulator.

The baseband filter 105 selectively extracts a specified frequency component from the output signal of the mixer 104. The output signal of the baseband filter 105 is amplified by the variable gain amplifier 106 into a signal with an amplitude adapted for analog-digital conversion, which is then input to the analog-digital converter 107. The analog-digital converter 107 outputs a digital baseband signal.

The digital baseband signal is input to the baseband processing unit 108. The baseband processing unit 108 decodes the digital baseband signal. This allows obtaining received data.

Next, the transmitting circuit is described. The baseband processing unit 108 outputs a digital baseband signal generated based on transmitted data. The output digital baseband signal is converted into an analog signal by the digital-analog converter 109.

The baseband filter 110 removes an extraneous component from the analog signal. Then, the variable gain amplifier 111 amplifies the analog signal with the extraneous component removed into an amplified signal. The amplified signal is input to the mixer 112. The I/Q signal output from any one of the semiconductor integrated circuit devices 1 to 3 is also input to the mixer 112. The mixer 112 and any one of the semiconductor integrated circuit devices 1 to 3 configure a modulator.

The high-frequency filter 113 removes a high-frequency component from the output signal of the mixer 112. The power amplifier 114 amplifies the output signal of the high-frequency filter 113 up to the power level specified for transmission. Then, the antenna 101 transmits the amplified signal of the power amplifier 114 as a second radio signal.

The wireless communication apparatus 10 described above includes anyone of the semiconductor integrated circuit devices 1 to 3. Each of the semiconductor integrated circuit devices 1 to 3 uses much less power than other circuit devices and performs a stable calibration operation. Therefore, reception processing and transmission processing using the I/Q signal output from any one of the semiconductor integrated circuit devices 1 to 3 can be stabilized.

While certain embodiments have been described, these embodiments have been presented by way of example only, and are not intended to limit the scope of the present disclosure. Indeed, the embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure. Moreover, some or all of the above described embodiments can be combined when implemented.

1. A semiconductor integrated circuit device comprising:
an oscillator configured to oscillate at a variable oscillation frequency;
a frequency divider configured to oscillate at a variable free-running oscillation frequency, and having a frequency dividing range that transitions according to a variation in the free-running oscillation frequency; and
a control circuit configured to control the oscillator to vary the oscillation frequency during a calibration operation that adjusts the oscillation frequency, and configured to control the frequency divider to cause the frequency dividing range to transition based on an amount of variation of the oscillation frequency.

2. The semiconductor integrated circuit device according to claim 1, wherein the oscillator includes
a plurality of capacitors configured to vary the oscillation frequency, and
a plurality of first switches, each of which is respectively connected in series with one capacitor of the plurality of capacitors, and wherein
the control circuit is configured to vary the oscillation frequency by controlling the plurality of first switches.

3. The semiconductor integrated circuit device according to claim 2, wherein the frequency divider includes
a frequency dividing circuit,
a plurality of current sources that are connected with the frequency dividing circuit and are configured to supply, to the frequency dividing circuit, a bias current that varies the free-running oscillation frequency, and
a plurality of second switches, each of which is respectively connected in series with one current source of the plurality of current sources, and wherein
the control circuit is configured to vary the free-running oscillation frequency by controlling the plurality of second switches to set the bias current.

4. The semiconductor integrated circuit device according to claim 3, wherein the control circuit is configured to set a target frequency of the free-running oscillation frequency corresponding to the amount of variation of the oscillation frequency, and is configured to set the bias current based on the set target frequency.

5. The semiconductor integrated circuit device according to claim 1, further comprising:
a variable frequency divider configured to frequency-divide a signal output from the frequency divider by a frequency division ratio set by the control circuit,
wherein the control circuit is configured to control the oscillator and the frequency divider based on a difference in frequency between a signal output from the variable frequency divider and a reference signal.

6. The semiconductor integrated circuit device according to claim 1, further comprising:
a phase detector configured to detect a phase of a signal input from the frequency divider; and
a comparator configured to compare the phase detected by the phase detector with a reference phase and to output a phase difference between the phase detected by the phase detector and the reference phase,
wherein the control circuit is configured to control the oscillator and the frequency divider based on the phase difference.

7. A wireless communication apparatus comprising:
the semiconductor integrated circuit device according to claim 1;
an antenna configured to receive a first radio signal and to transmit a second radio signal;
a receiving circuit configured to process the first radio signal using an output signal of the semiconductor integrated circuit device;
a transmitting circuit configured to generate the second radio signal using the output signal of the semiconductor integrated circuit device; and
a baseband processing unit configured to process a signal output from the receiving circuit and configured to generate a signal to be input to the transmitting circuit.

8. A semiconductor integrated circuit device comprising:
an oscillator configured to oscillate at a variable oscillation frequency;
a first frequency divider configured to oscillate at a variable free-running oscillation frequency, and having a first frequency dividing range that transitions according to the free-running oscillation frequency;
a second frequency divider having a second frequency dividing range that transitions according to the free-running oscillation frequency, the second frequency dividing range of the second frequency divider being narrower than the first frequency dividing range of the first frequency divider; and
a control circuit configured to control the oscillator to vary the oscillation frequency during a first calibration operation that adjusts the oscillation frequency by causing the first frequency divider to operate and causing the second frequency divider to stop, and configured to adjust the free-running oscillation frequency during a second calibration operation by causing the first frequency divider to stop and causing the second frequency divider to operate.

9. The semiconductor integrated circuit device according to claim 8, wherein the control circuit is configured to perform the first calibration operation prior to the second calibration operation.

10. A semiconductor integrated circuit device comprising:
a digital phase detector;
a digital comparator;
an oscillator;
a frequency divider; and
a control circuit, wherein
the digital phase detector is configured to detect and output a phase of a feedback signal output from the frequency divider based on a reference signal,
the digital comparator is configured to compare a reference phase and the phase output from the digital phase detector, and is configured to output a signal indicating a difference between the reference phase and the phase output from the digital phase detector,
the oscillator is configured to oscillate at a variable oscillation frequency and is configured to output an oscillating signal,
the frequency divider has a frequency dividing range that transitions according to the variable oscillation frequency, and is configured to frequency-divide the oscillating signal output from the oscillator, and is configured to output a corresponding I/Q signal and the feedback signal, and
the control circuit is configured to perform a calibration operation of the oscillator and a calibration operation of the frequency divider based on the signal output from the digital comparator, and to control the frequency divider to cause the frequency dividing range to transition based on an amount of variation of the oscillation frequency.

11. The semiconductor integrated circuit device of claim 10, wherein the digital comparator is configured to obtain the reference phase by cumulating a frequency control code that indicates how many cycles of a desired frequency to which one cycle of the reference signal corresponds.
